(19) United States
(12) Patent Application Publication
(10) Pub. No.: US 2005/0116271 A1
(43) Pub. Date: Jun. 2, 2005

(54) Solid-state imaging device and manufacturing method thereof

(76) Inventor: Yoshiaki Kato, Kusatsu-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/994,460

(22) Filed: Nov. 23, 2004

(30) Foreign Application Priority Data
Dec. 2, 2003 (JP) 2003-403157
Dec. 9, 2003 (JP) 2003-410431

(51) Int. Cl. H01L 27/148

(52) U.S. Cl. 257/292

(57) ABSTRACT

The solid-state imaging device according to the present invention comprises: the photodiode 1 which converts the incident light into charge; the first dielectric film 82 formed above the photodiode 1; the second dielectric film 83 and the third dielectric film 21 formed above the first dielectric film 82; and the hollow layer 9 formed between either two of the first, second and third dielectric films.

### BACKGROUND OF THE INVENTION

(1) Field of the Invention

The present invention relates to a solid-state imaging device implemented in a digital still camera or a built-in video camera, and to a manufacturing method thereof.

(2) Description of the Related Art

In recent years, a solid-state imaging device has been widely used for the imaging unit in a built-in video camera and a digital still camera. Among such solid-state imaging devices, in particular, an interline transfer-CCD solid-state imaging device (hereinafter referred to as IT-CCD) has been noted for its low-noise characteristic.

FIG. 1 is a schematic diagram showing the structure of a general IT-CCD.

As shown in FIG. 1, a solid-state imaging device 100 comprises: a photodiode 1 including a photoelectric conversion function; a vertical transfer unit 2 which has an embedded channel structure in which signal charge is transferred in vertical direction; a vertical transfer gate 3 which controls the vertical transfer; a horizontal transfer unit 4 which transfers the signal charge in horizontal direction; and an output unit 5.

FIG. 2 is a diagram showing a unit pixel 200 which comprises: as shown in FIG. 1, a photodiode 1; a vertical transfer unit 2; and a vertical transfer gate 3.

FIG. 3 is a cross-sectional schematic diagram of the unit pixel 200 from A to A′ as shown in FIG. 2.

As shown in FIG. 3, the unit pixel 200 comprises: a photodiode 1 including a photoelectric conversion function formed in a silicon substrate 11; a vertical transfer unit 2 which has an embedded channel structure in which signal charge is transferred in vertical direction; a vertical transfer gate 3 which controls the vertical transfer; a dielectric film 81 which is formed above the vertical transfer gate 3, and consists primarily of SiO₂; a light-proof film 6 which is formed on the dielectric film 81, and prevents incident light from entering the regions such as the vertical transfer unit 2 and the vertical transfer gate 3; a dielectric film 82 which is formed above the light-proof film 6 and the photodiode 1, and consists primarily of SiO₂; a protective film 10 formed on the dielectric film 82; an organic dielectric film 12 formed above the protective film 10; and a lens 7 formed, on the dielectric film 12, using an organic film for condensing the incident light into the photodiode 1.

The dielectric film 12 has a double function of flattening and a color filter.

Also, various methods have been suggested regarding the manufacturing method for the solid-state imaging device. The patent literatures such as Japanese patent publication No. 2869280 and Japanese Laid-Open patent application No. H7-45805 disclose the above mentioned methods.

FIG. 4A and FIG. 4B are diagrams showing a part of the conventional manufacturing method for the solid-state imaging device. In FIG. 4A, (i) a light-proof film 6 is formed, (ii) a dielectric film 82 is formed above the light-proof film 6, and (iii) a protective film 10 is formed on the dielectric film 82. After that, as shown in FIG. 4B, an organic dielectric film 12 is formed above the protective film 10, and a lens 7 is formed above the dielectric film 12.

However, according to the conventional solid-state imaging device, there is a problem that in the case where light condensing of the lens is not adequate, the incident light is not condensed into the photodiode, thus the incident light cannot be effectively utilized.

In other words, when the incident light vertically enters the solid-state imaging device, the light is efficiently condensed into the lens 7, and effectively enters the photodiode 1. However, when the incident angle deviates from vertical, the light is not condensed into the photodiode 1. And, as shown in FIG. 9, the light diffuses on the surface of the light-proof film 6, and the incident light cannot be used effectively.

In particular, along with the recent miniaturization of a camera, miniaturization of the unit pixel and shortening of eye relief of the lens used in the camera are required for the solid-state imaging device.

The miniaturization of the unit pixel reduces the width of the opening of the photodiode 1 which is the opening of the light-proof film 6. Thus, the film thickness of the vertical transfer gate 3 cannot be made thin, due to the reduction ratio of the opening width. Thereby, the structure of the unit pixel 200 becomes a shaft shape, and condensing the incident light becomes difficult.

Also, the shortening of the eye relief of the camera lens means the increase of the light whose incident angle deviates from vertical to the solid-state imaging device. And, this makes the effective condensing of the incident light into the photodiode 1 difficult, as well.

In addition, the patent literature, Japanese patent publication No. 2869280 discloses the technique which (i) applies water-soluble resin, (ii) covers the water-soluble resin with another resin, and (iii) later dissolves the water-soluble resin so as to form a gas layer. However, according to the conventional technique, it is difficult to thinly and uniformly apply the water-soluble resin on the bumpy surface of the solid-state imaging device. And, (i) liquid pool may be generated in the concave part, (ii) the whole concave part may be filled with resin, or (iii) a foam-like region where the resin cannot be applied to may be generated in a portion of the concave part. Therefore, according to the above mentioned manufacturing method, a characteristic of uniformity cannot be acquired.

Moreover, the Japanese Laid-Open patent application No. H7-45805 discloses the technique which uses a material such as titanium oxide film whose refractive index is about 2.0, and utilizes the total reflection in the boundary so as to improve the light condensing. However, the material which has a high refractive index also has a high absorption index of light. Thereby, there is a harmful effect that the light may be decayed before entering the photodiode. Such effect is noticeable in the short wavelength side of the visible region, and the color balance of the incident light tends to be concentrated in red.

### SUMMARY OF THE INVENTION

The object of the present invention, in view of the above mentioned problems is to provide a solid-state imaging device in which incident light is condensed efficiently into a photodiode, and a method thereof.

In order to achieve the above mentioned object, the solid-state imaging device according to the present invention comprises: a photoelectric conversion unit operable to convert incident light into electric charge; a first dielectric film formed above the electric conversion unit; a second dielectric film and a third dielectric film formed above the first dielectric film; and a hollow layer placed between either two of the first, second and third dielectric films.

Also, the second dielectric film is formed contacting a part above an opening of the photoelectric conversion unit of the first dielectric film, without contacting the other part, separating the first dielectric film and the hollow layer, and the third dielectric film is formed contacting the hollow layer side of the second dielectric film without contacting the first dielectric film.

In addition, the third dielectric film is formed contacting a part above an opening of the photoelectric conversion unit of the first dielectric film, without contacting the other part, separating the first dielectric film and the hollow layer, and the second dielectric film is formed contacting the third dielectric film.

Moreover, the second dielectric film is formed only contacting a part above an opening of the photoelectric conversion unit of the first dielectric film, and the third dielectric film is formed contacting the side of the second dielectric film, and includes the hollow layer inside.

The second dielectric film has a funnel shape whose opening size becomes larger as a location of the film deviates from the photoelectric conversion unit.

The refractive index of the third dielectric film is higher than the refractive index of the second dielectric film.

The refractive index of the second dielectric film is 1.4 or higher and smaller than 1.6, and the refractive index of the third dielectric film is 1.6 or higher and smaller than 3.4.

At least one of the first, second and third dielectric films is an inorganic dielectric film.

The atmospheric pressure of the hollow layer is 0.5 or less.

According to the structure of the present invention, due to the refractive index difference caused in the boundary between the hollow layer and the dielectric film, total reflection of the incident light can be generated. Thus, the incident light can be efficiently condensed into the photodiode. In particular, even in the case where (i) the solid-state imaging device has a structure of a narrow shaft shape, or (ii) the incident light angle to the solid-state imaging device deviates from vertical, the incident light can be efficiently condensed. Also, most of the top part of the photodiode can be formed using low refractive material. Therefore, the effect of the total reflection can be maximized, and attenuation of the incident light before entering the photodiode can be minimized.

Also, the hollow layer has low atmospheric pressure, and the refractive index is close to the vacuum refractive index. The refractive index difference between the hollow layer and the dielectric film can be increased. Thereby, the incident light can be condensed into the photodiode more efficiently.

Thus, the sensitivity of the solid-state imaging device can be improved.

The solid-state imaging device according to the present invention further comprises a charge transfer unit operable to transfer charge accumulated in the photoelectric conversion unit to a predetermined direction, said unit being formed adjacently to the photoelectric conversion unit.

The solid-state imaging device further comprises a charge detection unit operable to convert electric charge accumulated in the photoelectric conversion unit into voltage, said charge detection unit formed adjacently to the photoelectric conversion unit.

The method for manufacturing the solid-state imaging device according to the present invention comprises: forming the first dielectric film above the photoelectric conversion unit; forming a fourth dielectric film above the first dielectric film; and selectively etching the fourth dielectric film.

The method for manufacturing the solid-state imaging device further comprises: forming the third dielectric film above the fourth dielectric film; etching and removing a part of the third and fourth dielectric films above an opening of the photoelectric conversion unit; forming the second dielectric film above a part of the first and the third dielectric films above an opening of the photoelectric conversion unit; flattening the second dielectric film; and selectively etching and removing the second and third dielectric films up to above the fourth dielectric film, in an outer boundary part of the photoelectric conversion unit, wherein in the selective etching, the fourth dielectric film is selectively and isotropically etched using the first, second and third dielectric films as masks.

The method for manufacturing the solid-state imaging device further comprises: etching and removing a part of the fourth dielectric film above an opening of the photoelectric conversion unit; forming the third dielectric film above a part of the first and the fourth dielectric films above an opening of the photoelectric conversion unit; forming the second dielectric film above the third dielectric film; flattening the second dielectric film; and selectively etching and removing the second and third dielectric films up to above the fourth dielectric film, in an outer boundary part of the photoelectric conversion unit, wherein in the selective etching, the fourth dielectric film is selectively and isotropically etched using the first, second and third dielectric films as masks.

The method for manufacturing the solid-state imaging device further comprises: etching a part of the fourth dielectric film above an opening of the photoelectric conversion unit; forming and flattening the second dielectric film above the first and the fourth dielectric films; and selectively etching the second dielectric film up to above the fourth dielectric film, said second dielectric film being above an outer boundary part of the photoelectric conversion unit, wherein in the selective etching, the fourth dielectric film surrounded by the first and second dielectric films is selectively etched using the first and second dielectric films as masks, and a concave part is formed so as to form the third dielectric film which boxes the follow layer in the concave part.

In the formation of the third dielectric film, a Chemical-Vapor Deposition (CVD) method is used, and by accelerating a speed of forming the film in the middle of the formation, the boxed hollow layer is formed.

Also, the formation of the third dielectric film is executed under decompression state.

Thus, the dielectric film in the boundary of the hollow layer can be formed at the same time as the boxing process of the hollow structure. Thereby, the manufacturing cost of the solid-state imaging device can be reduced. Also, the uniformity of the formed films can be achieved. In addition, since the photoresist is not used in time of etching the hollow layer, a good selectivity can be acquired.

Moreover, in the formation of the third dielectric film, a protective film is formed by continuing the formation of the film just after boxing the hollow layer in.

Therefore, the manufacturing process of the solid-state imaging device can be curtailed.

Furthermore, the fourth dielectric film is a dielectric film or a conductive film which has a refractory metal component whose melting point is 700° C. or higher.

Since the film reacts to the active species such as fluorine (F) and chlorine (Cl) easily, the film can be removed by etching easily.

### FURTHER INFORMATION ABOUT TECHNICAL BACKGROUND TO THIS APPLICATION

The disclosures of Japanese Patent Application No. 2003-403157 filed on Dec. 2, 2003 and Japanese Patent Application No. 2003-410431 filed on Dec. 9, 2003 including specifications, drawings and claims are incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 5 is a diagram showing the cross-sectional structure of the solid-state imaging device according to the first embodiment of the present invention;

FIG. 6A to FIG. 6F are diagrams showing the manufacturing method of the solid-state imaging device according to the first embodiment of the present invention;

FIG. 7 is a diagram showing the cross-sectional structure of the solid-state imaging device according to the second embodiment;

FIG. 8A to FIG. 8F are diagrams showing the manufacturing method of the solid-state imaging device according to the second embodiment;

FIG. 9 is a diagram showing the cross-sectional structure of the solid-state imaging device according to the third embodiment;

FIG. 10A to FIG. 10F are diagrams showing the manufacturing method for the solid-state imaging device according to the third embodiment;

FIG. 1 is a schematic top view of the conventional solid-state imaging device;

FIG. 2 is a schematic top view of the unit pixel of the conventional solid-state imaging device;

FIG. 3 is a diagram showing the cross-sectional structure of the conventional solid-state imaging device; and

FIG. 4A and FIG. 4B are diagrams showing the conventional manufacturing method for the solid-state imaging device.

### DESCRIPTION OF THE PREFERRED EMBODIMENT(S)

### First Embodiment

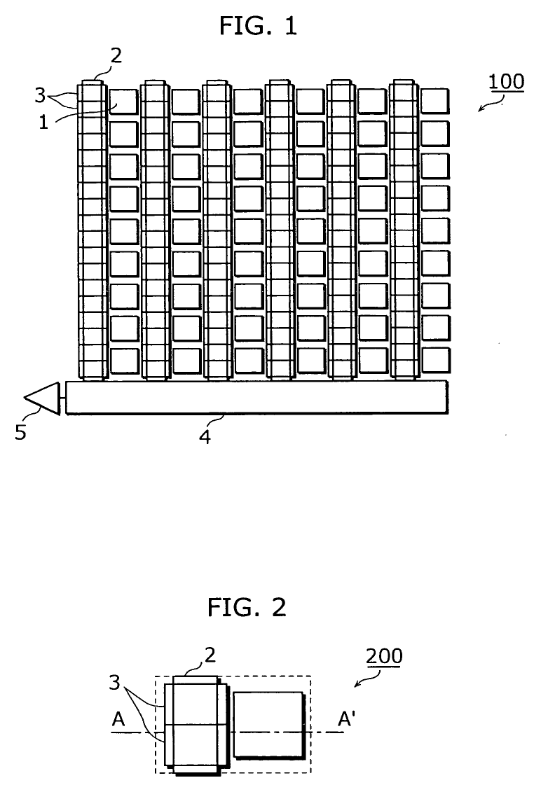

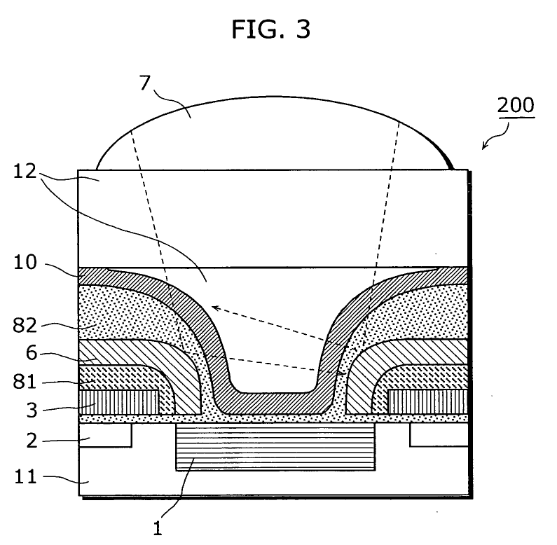

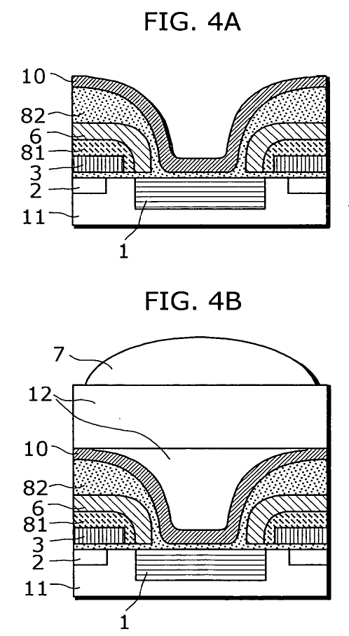

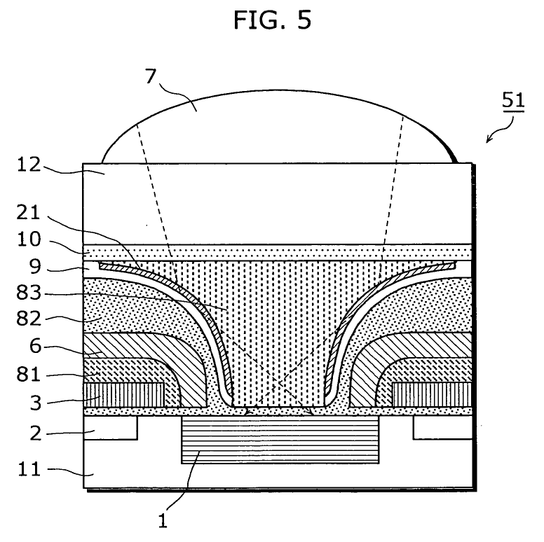

FIG. 5 is a diagram showing the cross-sectional structure of the solid-state imaging device according to the first embodiment of the present invention.

In FIG. 5, the solid-state imaging device 51 comprises: a photodiode 1 including a photoelectric conversion function; a vertical transfer unit 2 which has an embedded channel structure in which signal charge is transferred in vertical direction; a vertical transfer gate 3 which controls the vertical transfer; a light-proof film 6 which causes incident light to enter the photodiode 1, and prevents the incident light from entering the other regions such as the vertical transfer unit 2; dielectric films 81, 82 and 83 which consist primarily of SiO₂; a dielectric film 21 which consists primarily of SiON; a protective film 10; an organic dielectric film 12 which has a double function of flattening and color filter; a lens 7 formed using an organic film for condensing the incident light into the photodiode 1; a silicon substrate 11; and a hollow layer 9 between the dielectric film 82 and the dielectric film 21.

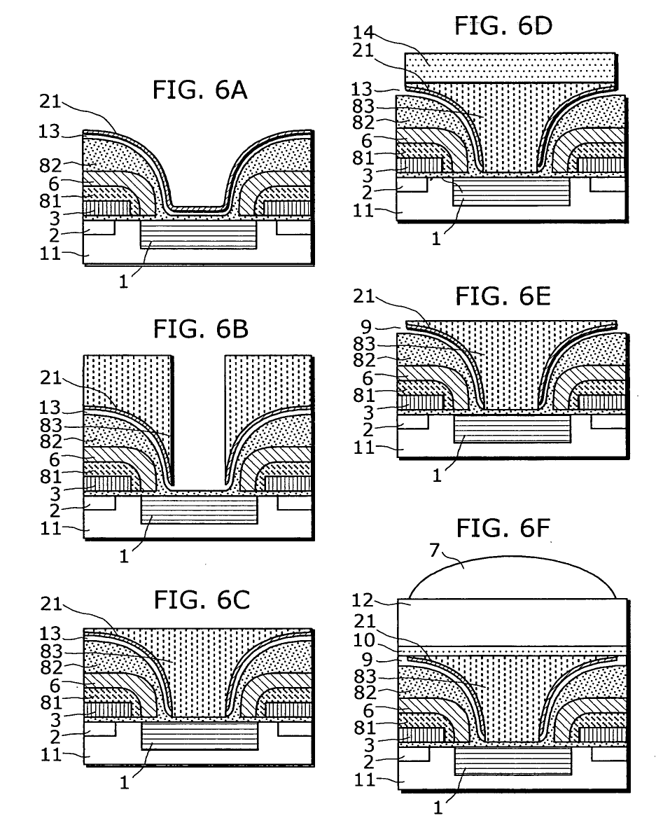

FIG. 6A to FIG. 6F are diagrams showing the manufacturing method of the solid-state imaging device according to the first embodiment of the present invention.

In FIG. 6A, after the light-proof film 6 and the dielectric film 82 are formed, the dielectric film 13 which consists primarily of SiN, and the dielectric film 21 which consists primarily of SiON are formed. This can be achieved by using a method for forming a SiN film or a SiON film such as Chemical-Vapor Deposition (CVD) which uses, for example, plasma and ultraviolet (UV) so as to lower the formation temperature of the films. The same method as the conventional method for manufacturing the solid-state imaging device can be used up to the formation of the dielectric film 82.

Next, as shown in FIG. 6B, the photoresist 14 is patterned so as to create an opening above the photodiode 1. And, the dielectric film 13 and the dielectric film 21 are etched.

Then, as shown in FIG. 6C, the photoresist 14 is removed, and the dielectric film 83 is formed and flattened.

In FIG. 6D the dielectric film 83 and the dielectric film 21 are etched in the boundary part of the adjacent photodiode 1, using the photoresist 14.

Next, as shown in FIG. 6E, the photoresist 14 is removed, and the dielectric film 13 which consists primarily of SiN is isotropically etched from the part where etching has been executed in the boundary part of the adjacent photodiode to the previously formed dielectric film 83, so as to form the hollow layer 9.

In such case as described above, for example, by executing dry etching using gas such as CF₄ and CCL₄ which consist primarily of fluorine (F) and chlorine (Cl) used for etching, only the dielectric film 13 which primarily consists of SiN can be selectively removed.

Then, as shown in FIG. 6F, the protective film 10 is formed so as to cover the whole, and the organic film 12 and the lens 7 using the organic film are formed. As well as the conventional example, the organic film 12 has a double function of flattening and color filter.

According to the first embodiment structured as described above, in the boundary part between the hollow layer 9 and the dielectric film 21, the dielectric film 21 has a higher refractive index. The dielectric constant of the hollow layer 9 is equivalent to the vacuum dielectric constant of 1. Thus, in the interface between the dielectric film 21 and the hollow layer 9, total reflection occurs depending on the refractive index difference.

Assuming the refractive index of the dielectric film 21 is n, the total reflection angle ⊖ fulfills the following equation.
cos⊖=1/n (1)
For example, in the case where n equals 2.0, according to the equation (1), ⊖ equals 60.0°. This means that the total reflection occurs from the surface adjoining the current point in the boundary between the dielectric film 21 and the hollow layer 9 up to the degree of 60.0°.

For example, in the case where (i) the dielectric film 83 is formed using the SiO₂ film whose refractive index is 1.4 or higher and smaller than 1.6, and (ii) the dielectric film 21 is formed using the SiON film whose refractive index is 1.6 or higher and smaller than 3.4, without the dielectric film 21, the total reflection angle is 44.4 degrees or larger, and smaller than 51.3 degrees, but with the dielectric film 21, the total reflection angle becomes 51.3 degrees or larger and 72.8 degrees or smaller. Thus, the conditions for the total reflection become flexible. Therefore, even if the light condensing into the opening part of the photo diode by the lens 7 is inadequate, using the guide function for the incident light generated by the total reflection in the interface of the hollow layer 9, the incident light can be effectively condensed into the photodiode 1.

Since the SiN film 13 is formed using the film-formation method such as the CVD method, the non-uniformity of the formed film which is a problem in the manufacturing method for applying the water-soluble resin as disclosed in the Japanese patent publication No. 2869280 is not a problem in the present manufacturing method.

Also, if Si film is used in stead of SiN film 13, Si reacts to active species such as F and Cl more easily, thus an even better etching characteristic can be acquired.

In addition, if a film which consists of refractory metal such as Ti film and TiN film whose melting point is 700° C. or higher is used, in stead of the SiN film 13, such film reacts to active species such as F and Cl more easily, thus the film can be more easily removed by etching.

Moreover, when the hollow layer 9 is etched, the organic photoreist is not used, and the patterned dielectric film 83 is used in stead of the photoresist. If the photoresist is used in time of the dry etching, the product material which generated from the photoresist in the middle of the etching becomes the etching active species, and selectivity is lowered. However, according to the technique of the present invention, since the photoresist is not used in time of etching the hollow layer, a good selectivity can be acquired.

### Second Embodiment

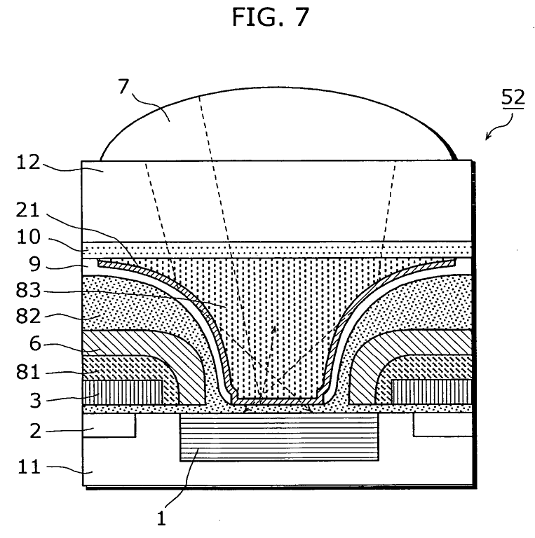

FIG. 7 is a diagram showing the cross-sectional structure of the solid-state imaging device according to the second embodiment of the present invention.

The solid-state imaging device according to the second embodiment is different from that of the first embodiment in that the dielectric film 21 is placed on the photodiode 1, and forms the multilayered structure with the SiO₂ film 82 above the interface of the Si substrate 11 including the photodiode 1.

As shown in FIG. 7, the solid-state imaging device 52 comprises: a photodiode 1; a vertical transfer unit 2; a vertical transfer gate 3; a light-proof film 6 which causes incident light to enter the photodiode 1, and prevents the incident light from entering the other regions such as the vertical transfer unit 2; dielectric films 81, 82 and 83 which consist primarily of SiO₂; a dielectric film 21 which consists primarily of SiON; a protective film 10; an organic dielectric film 12 which has a double function of flattening and color filter; a lens 7 formed using an organic film for condensing the incident light into the photodiode 1; a silicon substrate 11; and a hollow layer 9 between the dielectric film 82 and the dielectric film 21 other than above the opening part of the photodiode.

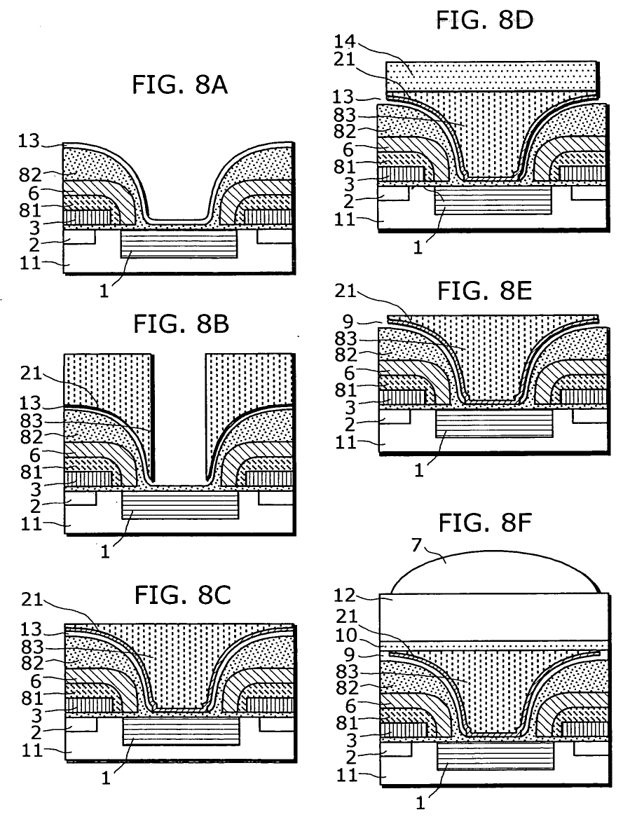

FIG. 8A to FIG. 8F are diagrams showing the manufacturing method for the solid-state imaging device according to the second embodiment.

In FIG. 8A, after the light-proof film 6 and the dielectric film 82 are formed, the dielectric film 13 which consists primarily of SiN is formed. This can be achieved by using a method for forming a SiN film such as CVD which uses, for example, plasma and UV so as to lower the formation temperature of the film. The same method as the conventional method for manufacturing the solid-state imaging device can be used up to the formation of the dielectric film 82.

Next, as shown in FIG. 8B, the photoresist 14 is patterned so as to create an opening above the photodiode 1. Thereby, the dielectric film 13 is etched.

Then, as shown in FIG. 8C, the photoresist 14 is removed, and the dielectric films 21 and 83 are formed and flattened.

The formation of the dielectric film 21 can be achieved by the formation method such as CVD which uses, for example, plasma and UV so as to lower the formation temperature of the films.

In FIG. 8D the dielectric film 83 and the dielectric film 21 are etched in the boundary part of the adjacent photodiode 1, using the photoresist 14.

Next, as shown in FIG. 8E, the photoresist 14 is removed, and the dielectric film 13 which consists primarily of SiN is isotropically etched from the part where etching has been executed in the boundary part of the adjacent photodiode to the previously formed dielectric film 83, so as to form the hollow layer 9.

In such case as described above, for example, by executing dry etching using gas such as CF₄ and CCL₄ which consist primarily of fluorine (F) and chlorine (Cl) used for etching, only the dielectric film 13 which primarily consists of SiN can be selectively removed.

Then, as shown in FIG. 8F, the protective film 10 is formed so as to cover the whole, and the organic film 12 and the lens 7 using the organic film are formed. As well as the conventional example, the organic film 12 has a double function of flattening and color filter.

According to the second embodiment as described above, as well as the first embodiment, due to the refractive index difference acquired in the boundary part between the hollow layer 9 and the dielectric film 21, the total reflection is generated in the boundary so as to effectively guide the incident light into the photodiode.

According to the second embodiment of the present invention, the dielectric film 21 is placed above the photodiode 1 as well, and forms the multilayered structure with the SiO₂ film 82 above the interface of the Si substrate 11 including the photodiode 1.

In the interface of the Si substrate including the photodiode 1, due to the refractive index difference between SiO₂ and Si, light reflection occurs. However, anti-reflection effect can be acquired due to the multilayered structure of the dielectric film 21 and SiON film. Thus, the incidence efficiency of light into the photodiode 1 can be improved.

Also, according to the second embodiment of the present invention, when the light guiding structure which uses the total reflection around the photodiode 1 is formed, at the same time, the anti-reflection structure can be formed.

In addition, according to the second embodiment, when the guiding structure for the incident light using the total reflection is formed, the anti-reflection structure can be formed in the interface of the Si substrate including the photodiode 1. Thereby, while acquiring further light condensing effect, manufacturing cost can be reduced.

Such technique as described above can deal with (i) the deepened shaft shape of the photodiode caused by the miniaturization of the unit pixel of the solid-state imaging device, and (ii) the change of the incident light angle caused by the shortened eye relief of the camera lens. Therefore, a good imaging characteristic can be acquired which assures a substantial practical effect.

According to the first and second embodiments of the present invention, the CCD solid-state imaging device is used as an example. Needless to say, the same effects can be acquired using a Metal Oxide Semiconductor (MOS) solid-state imaging device.

Also, the present invention can be applied to any other solid-state imaging devices as long as the solid-state imaging device comprises a photodiode which has a photoelectric conversion function.

Moreover, in the case where the unit pixel is miniaturized in plane direction, and the photodiode plane is located in the deep bottom, the hollow layer may have a shape which is vertical from the origin point above the photodiode, or partially approaching the center of the photodiode in the deep bottom, and rises in the form to narrow the opening so as to widen the opening in the upper part. Needless to say, in such case as described above, the light condensed in the upper part is efficiently guided, by the total reflection, into the photodiode which is located in the deep bottom. Thus, the present invention can be applied to the above mentioned case as well.

Furthermore, even in the case where the hollow layer does not have the shape which is vertical from the origin point above the photodiode, or partially approaching the center of the photodiode in the deep bottom, and rises in the form to narrow the opening so as to widen the opening in the upper part, the light condensed in the upper part can be efficiently guided, by the total reflection, into the photodiode which is located in the deep bottom. Thus, the guiding effect for the incident light by the total reflection using the hollow layer, according to the present invention, can be adequately acquired, and it is evident that the same effects can be acquired.

### Third Embodiment

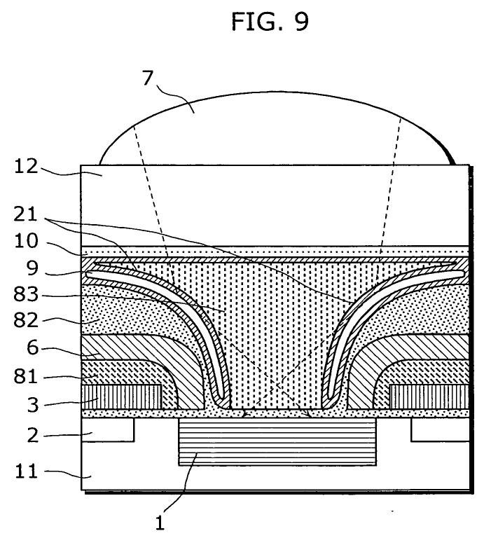

FIG. 9 is a diagram showing the cross-sectional structure of the solid-state imaging device according to the third embodiment.

As shown in FIG. 9, the unit pixel 201 comprises: a photodiode 1 including a photoelectric conversion function formed in a silicon substrate 11; a vertical transfer unit 2 which has an embedded channel structure in which signal charge is transferred in vertical direction; a vertical transfer gate 3 which controls the vertical transfer; a dielectric film 81 which is formed above the vertical transfer gate 3, and consists primarily of SiO₂; a light-proof film 6 which is formed above the dielectric film 81, and prevents incident light from entering the regions such as the vertical transfer unit 2 and the vertical transfer gate 3; a dielectric film 82 which is formed above the light-proof film 6 and the photodiode 1, and consists primarily of SiO₂; a dielectric film 83 which adjoins the dielectric film 82 only above the opening part of the photodiode 1, formed in the funnel shape with which the opening size becomes larger as the distance from the photodiode 1 becomes farther, the film primarily consisting of SiO₂; a dielectric film 21 formed between the dielectric films 82 and 83, including the hollow layer 9 inside, and consisting primarily of SiN; a protective film 10 formed above the dielectric film 21; an organic dielectric film 12 formed above the protective film 10; and a lens 7 formed, above the dielectric film 12, using an organic film for condensing the incident light into the photodiode 1.

The dielectric film 12 has a double function of flattening and color filter.

According to the third embodiment structured as described above, in the boundary part between the hollow layer 9 and the SiN film 21, the SiN film 21 has a higher refractive index. The dielectric constant of the hollow layer 9 is equivalent to the vacuum dielectric constant of 1. Thus, in the interface between the SiN film 21 and the hollow layer 9, total reflection occurs depending on the refractive index difference.

Assuming the refractive index of the SiN film 21 is n, the total reflection angle ⊖ fulfills the following equation.
cos⊖=1/n (1)
For example, in the case where n equals 2.0, according to the equation (1), ⊖ equals 60.0°. This means that the total reflection occurs from the surface adjoining the current point in the boundary between the SiN film 21 and the hollow layer 9 up to the degree of 60.0°.

Therefore, even if the light condensing into the opening part of the photo diode by the lens 7 is inadequate, using the guide function for the incident light generated by the total reflection in the interface of the hollow layer 9, the incident light can be effectively condensed into the photodiode 1.

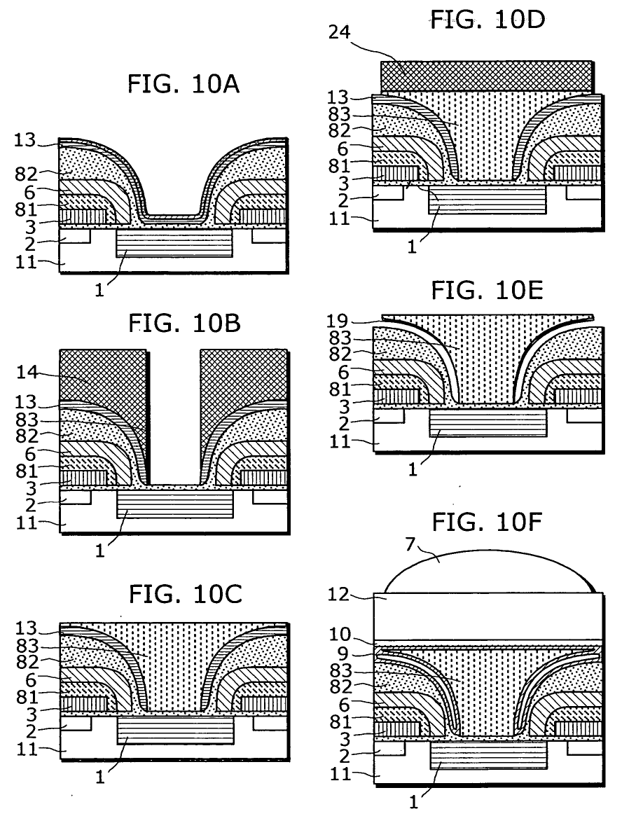

FIG. 10A to FIG. 10F are diagrams showing the manufacturing method for the solid-state imaging device according to the third embodiment.

In FIG. 10A, after the light-proof film 6 and the dielectric film 82 are formed, the dielectric film 13 which consists primarily of SiN is formed. This can be achieved by using a method for forming a SiN film such as CVD which uses, for example, plasma and UV so as to lower the formation temperature of the film. The same method as the conventional method for manufacturing the solid-state imaging device can be used up to the formation of the dielectric film 82.

Next, as shown in FIG. 10B, the photoresist 14 is patterned so as to create an opening above the photodiode 1. Thereby, the dielectric film 13 is etched.

Then, as shown in FIG. 10C, the photoresist 14 is removed, and the dielectric film 83 is formed and flattened above (i) the dielectric film 82 above the photodiode 1, and (ii) the dielectric film 13.

In FIG. 10D the dielectric film 83 is etched in the boundary part (above the light-proof film 6) of the adjoining pixel, using the photoresist 24.

Next, as shown in FIG. 10E, the photoresist 24 is removed, and the dielectric film 13 which consists primarily of SiN is etched from the part where etching has been executed in the boundary part of the adjoining pixel in the previously process, so as to form the hollow layer 19.

In FIG. 10F, SiN film 21 is formed, while boxing the hollow layer 9 inside the hollow layer 19, covering the surface of the dielectric film 83. Then, the protective film 10 is formed, covering the whole. And, above the protective film 10, the organic film 12 and the lens 7 using the organic film are formed in such order. The organic film 12 has a double function of flattening and color filter, as well as the conventional example.

Since the SiN film 13 is formed using the film-formation method such as the CVD method, the non-uniformity of the formed film which is a problem in the manufacturing method for applying the water-soluble resin as disclosed in the Japanese patent publication No. 2869280 is not a problem in the present manufacturing method.

In addition, if a dielectric film which consists of refractory metal such as Ti film and TiN film whose melting point is 700° C. or higher is used, in stead of the SiN film 13, such film reacts to active species such as F and Cl more easily, thus the film can be more easily removed by etching.

Moreover, when the hollow layer 19 is etched, the organic photoreist is not used, and the patterned dielectric films 82 and 83 are used in stead of the photoresist. If the photoresist is used in time of the dry etching, the product material which generated from the photoresist in the middle of the etching becomes the etching active species, and selectivity is lowered. However, according to the technique of the present invention, since the photoresist is not used in time of etching the hollow layer, a good selectivity can be acquired.

Also, for the formation of the SiN film 21, the formation method such as plasma CVD and UV-CVD in which a film having a low temperature and good uniformity can be acquired is used. Here, at the beginning of the formation, in order to uniformly form the film inside the hollow layer 19, the film is formed, for example, under the condition that the gas quantity is reduced than usual. Then, in mid-course, by restoring the usual formation condition, the film formation is rapidly executed in the opening of the pixel boundary region of the hollow layer 19, so as to box the hollow layer 9 in. In addition, since the film is formed in the state of decompression in the CVD process, by using such decompression, the hollow layer 9 can be boxed in while keeping the low atmospheric pressure.

Moreover, in the process of boxing in the hollow layer 9, by continuing the film formation just after the boxing, the protective film 10 can be simultaneously formed.

According to the embodiment of the present invention, the SiN film is used for forming the film to box in the hollow structure. However, even if other kinds of films such as SiON film is used, as long as the refractive index is 1.6 or higher, the same effects can be acquired.

According to the embodiments of the present invention, the CCD solid-state imaging device is used as an example. Needless to say, the same effects can be acquired using a Metal Oxide Semiconductor (MOS) solid-state imaging device.

Also, the present invention can be applied to any other solid-state imaging devices as long as the solid-state imaging device comprises a photodiode which has a photoelectric conversion function.

Moreover, in the case where the unit pixel is miniaturized in plane direction, and the photodiode plane is located in the deep bottom, the hollow layer may have a shape which is vertical from the origin point above the photodiode, or partially approaching the center of the photodiode in the deep bottom, and rises in the form to narrow the opening so as to widen the opening in the upper part. Needless to say, in such case as described above, the light condensed in the upper part is efficiently guided, by the total reflection, into the photodiode which is located in the deep bottom. Thus, the present invention can be applied to the above mentioned case as well.

Furthermore, even in the case where the hollow layer does not have the shape which is vertical from the origin point above the photodiode, or partially approaching the center of the photodiode in the deep bottom, and rises in the form to narrow the opening so as to widen the opening in the upper part, the light condensed in the upper part can be efficiently guided, by the total reflection, into the photodiode which is located in the deep bottom. Thus, the guiding effect for the incident light by the total reflection using the hollow layer, according to the present invention, can be adequately acquired, and it is evident that the same effects can be acquired.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be applied to a CCD solid-state imaging device, MOS solid-state imaging device, and the manufacturing method thereof, said solid-state imaging devices implemented in a digital still camera, a built-in video camera and the like.

1. A solid-state imaging device comprising:
a photoelectric conversion unit operable to convert incident light into electric charge;
a first dielectric film formed above the electric conversion unit;
a second dielectric film and a third dielectric film formed above the first dielectric film; and
a hollow layer placed (i) between either two or (ii) inside each of the first, second and third dielectric films.

2. The solid-state imaging device according to claim 1,
wherein the second dielectric film is formed (i) contacting a part above an opening of the photoelectric conversion unit of the first dielectric film, (ii) without contacting the other part, and (iii) separating the first dielectric film and the hollow layer, and
the third dielectric film is formed contacting the hollow layer side of the second dielectric film without contacting the first dielectric film.

3. The solid-state imaging device according to claim 1,
wherein the third dielectric film is formed contacting a part above an opening of the photoelectric conversion unit of the first dielectric film, without contacting the other part, separating the first dielectric film and the hollow layer, and
the second dielectric film is formed contacting the third dielectric film.

4. The solid-state imaging device according to claim 1,
wherein the second dielectric film is formed only contacting a part above an opening of the photoelectric conversion unit of the first dielectric film, and
the third dielectric film is formed contacting the side of the second dielectric film, and includes the hollow layer inside.

5. The solid-state imaging device according to claim 4,
wherein atmospheric pressure of the hollow layer is 0.5 or less.

6. The solid-state imaging device according to claim 1, further comprising a charge transfer unit operable to transfer charge accumulated in the photoelectric conversion unit to a predetermined direction, said unit being formed adjacently to the photoelectric conversion unit.

7. The solid-state imaging device according to claim 1, further comprising
a charge detection unit operable to convert electric charge accumulated in the photoelectric conversion unit into voltage, said charge detection unit being formed adjacently to the photoelectric conversion unit.

8. The solid-state imaging device according to claim 1,
wherein the second dielectric film has a funnel shape whose opening size becomes larger as a location of a location of the film deviates from the photoelectric conversion unit.

9. The solid-state imaging device according to claim 1,
wherein the refractive index of the third dielectric film is higher than the refractive index of the second dielectric film.

10. The solid-state imaging device according to claim 9,
wherein the refractive index of the second dielectric film is 1.4 or higher and smaller than 1.6, and the refractive index of the third dielectric film is 1.6 or higher and smaller than 3.4.

11. The solid-state imaging device according to claim 1,
wherein at least one of the first, second and third dielectric films is an inorganic dielectric film.

12. A method for manufacturing the solid-state imaging device according to claim 1, comprising:
forming the first dielectric film above the photoelectric conversion unit;
forming a fourth dielectric film above the first dielectric film; and
selectively etching the fourth dielectric film.

13. The method for manufacturing the solid-state imaging device according to claim 12, further comprising:
forming the third dielectric film above the fourth dielectric film;
etching and removing a part of the third and fourth dielectric films above an opening of the photoelectric conversion unit;
forming the second dielectric film above a part of the first and the third dielectric films above an opening of the photoelectric conversion unit;
flattening the second dielectric film; and
selectively etching and removing the second and third dielectric films up to above the fourth dielectric film, in an outer boundary part of the photoelectric conversion unit,
wherein in the selective etching, the fourth dielectric film is selectively and isotropically etched using the first, second and third dielectric films as masks.

14. The method for manufacturing the solid-state imaging device according to claim 12, further comprising:
etching and removing a part of the fourth dielectric film above an opening of the photoelectric conversion unit;
forming the third dielectric film above a part of the first and the fourth dielectric films above an opening of the photoelectric conversion unit;
forming the second dielectric film above the third dielectric film;
flattening the second dielectric film; and
selectively etching and removing the second and third dielectric films up to above the fourth dielectric film, in an outer boundary part of the photoelectric conversion unit,
wherein in the selective etching, the fourth dielectric film is selectively and isotropically etched using the first, second and third dielectric films as masks.

15. The method for manufacturing the solid-state imaging device according to claim 12, further comprising:
etching a part of the fourth dielectric film above an opening of the photoelectric conversion unit;
forming and flattening the second dielectric film above the first and the fourth dielectric films; and
selectively etching the second dielectric film up to above the fourth dielectric film, said second dielectric film being above an outer boundary part of the photoelectric conversion unit,
wherein in the selective etching, the fourth dielectric film surrounded by the first and second dielectric films is selectively etched using the first and second dielectric films as masks, and a concave part is formed so as to form the third dielectric film which boxes the follow layer in the concave part.

16. The manufacturing method for the solid-state imaging device according to claim 15,
wherein in the formation of the third dielectric film, a Chemical-Vapor Deposition method is used, and by accelerating a speed of forming the film in the middle of the formation, the boxed hollow layer is formed.

17. The method for manufacturing a solid-state imaging device according to claim 15,
wherein the formation of the third dielectric film is executed under decompression state.

18. The method for manufacturing a solid-state imaging device according to claim 15,
wherein in the formation of the third dielectric film, a protective film is formed by continuing the formation of the film just after boxing the hollow layer in.

19. The method for manufacturing a solid-state imaging device according to claim 12,
wherein the fourth dielectric film is a dielectric film or a conductive film which has a refractory metal component whose melting point is 700° C. or higher.
